(19) United States
(12) Patent Application Publication
(10) Pub. No.: US 2009/0027237 A1
(43) Pub. Date: Jan. 29, 2009

(54) KEY SYSTEM AND METHOD CAPABLE OF DETECTING IF A PLURALITY OF KEYS ARE TRIGGERED

(76) Inventor: Chia-Hsin Chen, Taipei (TW)

Correspondence Address: NORTH AMERICA INTELLECTUAL PROPERTY CORPORATION, P.O. BOX 506, MERRIFIELD, VA, 22116, US

(21) Appl. No.: 12/060,874

(22) Filed: Apr. 2, 2008

(30) Foreign Application Priority Data
Jul. 24, 2007 (TW) 096126913

(51) Int. Cl. H03M 11/00; H03K 17/94

(52) U.S. Cl. 341/26

(57) ABSTRACT

A key system includes a microcontroller and a plurality of keys. The first ends of the keys are coupled to a plurality of data input ports of the microcontroller respectively. The second ends of the keys are coupled to a key input port of the microcontroller. The key system utilizes the data signals inputted to the microcontroller as scan signals for the keys. The signal received by the key input port is detected to determine which key is triggered. Thus, only one key input port is sufficient to detect which of the plurality of keys is triggered.

### BACKGROUND OF THE INVENTION

1. Field of the Invention

The present invention relates to a key system, and more particularly, to a key system utilizing one key input port to detect a plurality of keys.

2. Description of the Prior Art

Monitors generally provide keys for users to adjust brightness, contrast, and color of the monitors. The keys are controlled by a microcontroller. In the prior art, the keys may be divided into a parallel key system and a scanning key system. The parallel key system controls one key with one I/O port of the microcontroller directly. The scanning key system outputs a scanning signal from the microcontroller and detects the scanning signal by a synchronal detection feedback unit so as to determine which key is triggered.

Please refer to FIG. 1. FIG. 1 is a diagram of a parallel key system according to the prior art. The parallel key system comprises a microcontroller 110, six keys 101˜106, and six resistors 111˜116. The keys 101˜106 have first ends coupled to a power supply, and second ends coupled to six key input ports 117 of the microcontroller 110 respectively. The resistors 111˜116 have first ends coupled to the six key input ports 117 of the microcontroller 110 respectively, and second ends coupled to a ground. Thus, when one of the keys 101˜106 is triggered, the key input port 117 of the microcontroller 110 reads the voltage of the power supply through the corresponding key to determine that the key is triggered.

Please refer to FIG. 2. FIG. 2 is a diagram of a scanning key system according to the prior art. The scanning key system comprises a microcontroller 210, six keys 201˜206, three diodes 211˜213, and two resistors 214˜215. The diodes 211˜213 are used for preventing the signals from returning to the key output ports 216 when several keys are triggered. The resistors 214˜215 are used for preventing the key input ports 217 from generating a floating voltage when no keys are triggered. The microcontroller 210 sends a scanning signal from the key output ports 216, and detects the scanning signal through the key input ports 217 to determine which key is triggered. In addition, three key output ports 216 have to output different scanning signals, so that the microcontroller 210 can determine which key is triggered according to the scanning signal. The six keys 201˜206 use three key output ports 216 and two key input ports 217. When the number of keys is greater than four, the scanning key system uses fewer I/O ports than the parallel key system.

In conclusion, the key systems according to the prior art, including the parallel key system and the scanning key system, require a lot of I/O ports of the microcontroller. However, I/O ports become rare in integrated circuits. Thus, if one I/O port can be used to control more keys, the microcontroller may incorporate more applications.

### SUMMARY OF THE INVENTION

According to an embodiment of the present invention, a key system capable of detecting if a plurality of keys are triggered comprising: a microcontroller comprising a first data input end, a second data input end, and a key input port; a first key, a first end of the first key coupled to the first data input end, and a second end of the first key coupled to the key input port; and a second key, a first end of the second key coupled to the second data input end, and a second end of the second key coupled to the key input port.

According to another embodiment of the present invention, a method of detecting if a plurality of keys are triggered comprising: providing a first key, a first end of the first key coupled to a first data input end of a microcontroller, and a second end of the first key coupled to a key input port of the microcontroller; providing a second key, a first end of the second key coupled to a second data input end of the microcontroller, and a second end of the second key coupled to the key input port of the microcontroller; and detecting a signal received by the key input port of the microcontroller to determine if the first key or the second key is triggered, or if the first key and the second key are triggered at the same time.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a parallel key system according to the prior art.

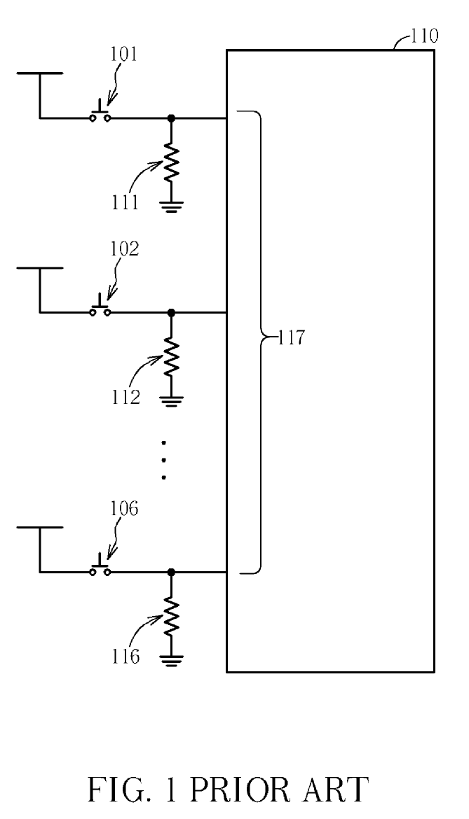

FIG. 2 is a diagram of a scanning key system according to the prior art.

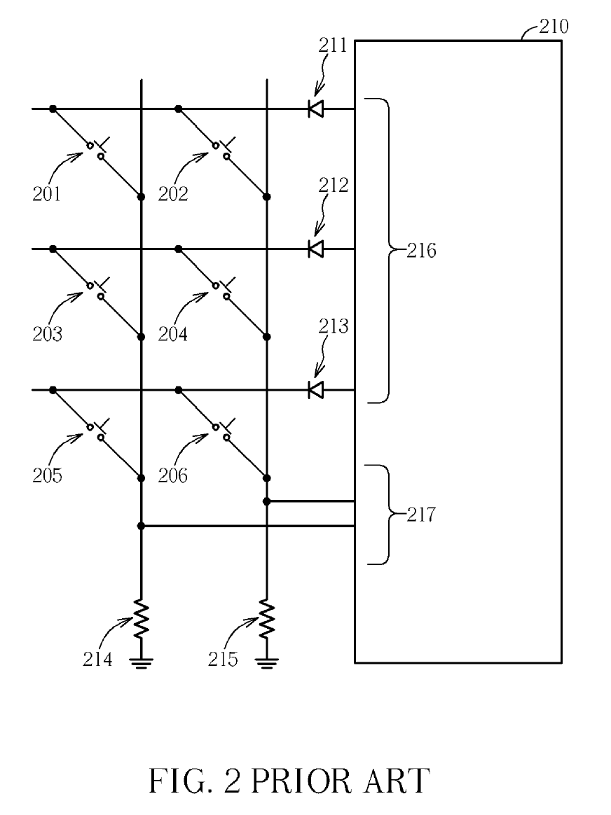

FIG. 3 is a diagram of a key system according to the present invention.

FIG. 4 is a diagram of the key detection unit of the microcontroller in FIG. 3.

FIG. 5 is an equivalent circuit of a double key.

FIG. 6 is a diagram of the double key detection unit of the microcontroller in FIG. 3.

FIG. 7 is a diagram of a reference signal generation unit of the microcontroller in FIG. 3.

FIG. 8 is a waveform diagram of a reference signal generated by a reference signal generation unit in FIG. 6.

FIG. 9 is a diagram of a reference signal control unit of the microcontroller.

### DETAILED DESCRIPTION

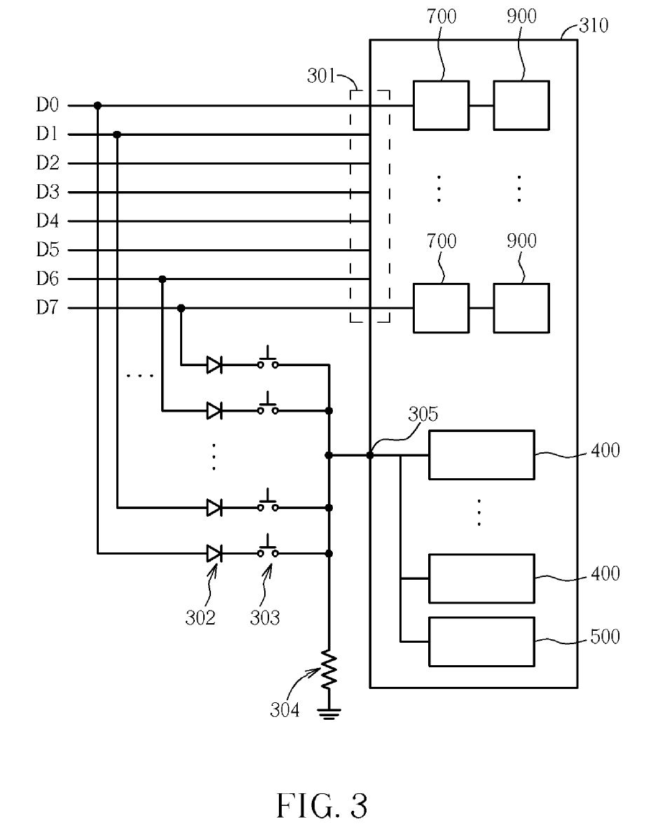

Please refer to FIG. 3. FIG. 3 is a diagram of a key system according to the present invention. The key system according to the present invention comprises a microcontroller 310 and a plurality of keys 303. The plurality of keys have first ends coupled to a plurality of data input ports 301 of the microcontroller 310 respectively, and second ends coupled to a key input port 305 of the microcontroller 310. The data signals inputted to the microcontroller 310 are used as scanning signals of the plurality of keys 303. The key system detects the signal received by the key input port 305 to determine which one of the plurality of keys 303 is triggered. Thus, only one key input port 305 is needed to detect the plurality of keys 303. In addition, a plurality of diodes 302 are coupled between the second ends of the plurality of keys 303 and the plurality of data input ports 301 for preventing the signals from returning to the data input ports 301 when several keys 303 are triggered. A pull-down resistor 304 is coupled between the key input port 305 and a ground for preventing the key input port 305 from generating a floating voltage when no keys are triggered. However, as integrated circuits advance, the pull-down resistor 304 may also be integrated in the microcontroller 310. In this embodiment, the data signals of the data input ports 301 are ITU656 signals. ITU656 is a standard for video and image transmission established by the International Telecommunication Union (ITU), which is used generally. In addition, the microcontroller 310 comprises a key detection unit 400 for determining the state of the keys, and a reference signal generation unit 700 and a reference signal control unit 900 for generating a reference signal.

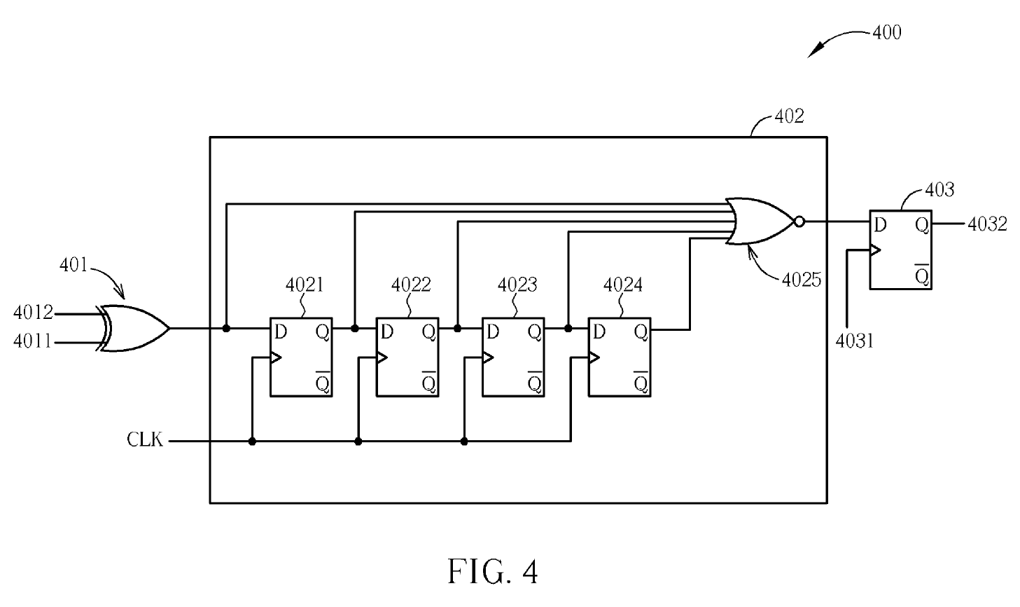

Please refer to FIG. 4. FIG. 4 is a diagram of the key detection unit 400 of the microcontroller 310 in FIG. 3. To determine if any key is triggered, each key has a corresponding key detection unit 400 in the microcontroller 310. The key detection unit 400 comprises an XOR gate 401, a check unit 402 and a re-sampling unit 403. The XOR gate 401 comprises an input signal end 4011 and a comparison signal end 4012. The input signal end 4011 is coupled to the key input port 305. The comparison signal end 4012 receives the data signals inputted to the data input port 301 or the reference signal generated by the microcontroller 310. The XOR gate 401 can determine if the signals of the input signal end 4011 and the comparison signal end 4012 are the same. The check unit 402 comprises a plurality of flip-flops 4021, 4022, 4023, 4024 and a NOR gate 4025. The plurality of flip-flops 4021, 4022, 4023, 4024 are coupled in series for storing successive bits outputted from the XOR gate 401. The input ends of the NOR gate 4025 are coupled to the positive input end of the plurality of flip-flops 4021, 4022, 4023, 4024 to generate a check result of the successive bits. If the check result is determined according to one output bit of the XOR gate 401, it is likely that the key detection unit 400 will make an erroneous judgment. Thus, the key detection unit 400 utilizes the check unit 402 to check the successive bits of the XOR gate 401 so as to reduce misjudgment. When the NOR gate 4025 outputs “1”, it represents the signals of the input signal end 4011 and the comparison signal end 4012 are the same, and indicates that the corresponding key is triggered. In addition, the re-sampling unit 403 can prevent the mechanical key from bouncing. The re-sampling unit 403 is a flip-flop, which utilizes a clock 4031 having a low frequency of the microcontroller 310 to re-sample the check result of the NOR gate 4025. Thus, the output 4032 signal of the re-sampling unit 403 can prevent bouncing.

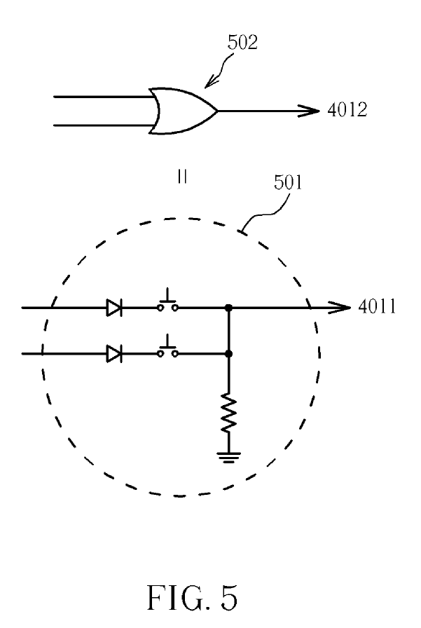

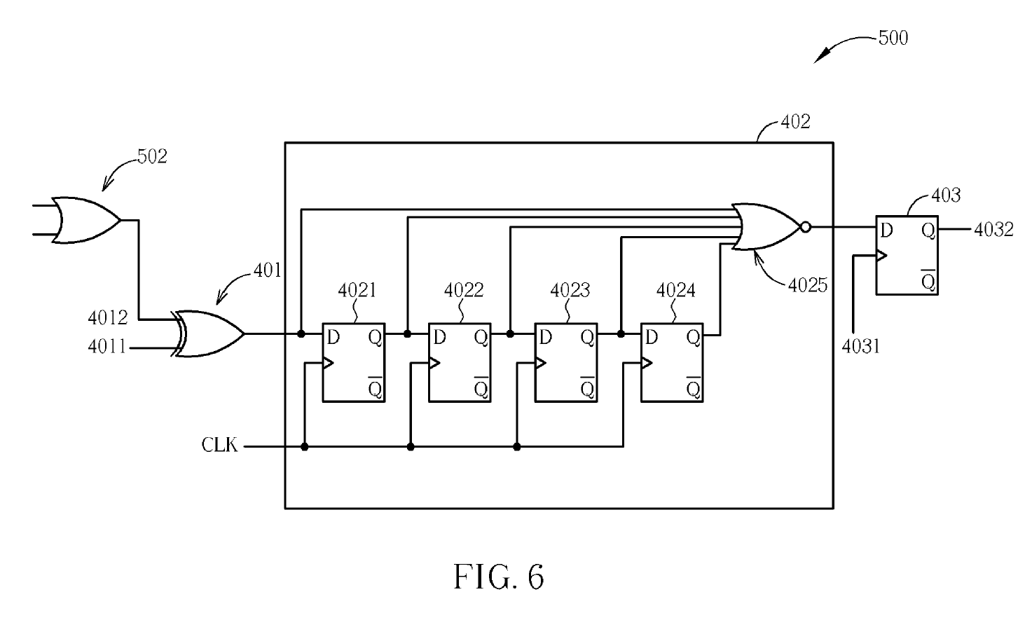

Please refer to FIG. 5 and FIG. 6. FIG. 5 is an equivalent circuit of the double key. FIG. 6 is a diagram of the double key detection unit 500 of the microcontroller 310 in FIG. 3. According to the embodiment of the key detection unit 400 in FIG. 4, each key has a corresponding key detection unit 400 for determining if the key is triggered. In addition, the key system according to the present invention can recognize that two keys are triggered at the same time. As shown in FIG. 5, when two keys are triggered at the same time, the equivalent circuit 501 of the two keys can be regarded as an OR gate 502. As shown in FIG. 6, the double key detection unit 500 comprises an OR gate 502 for generating a mixed signal corresponding to two keys. The mixed signal is inputted to the comparison signal end 4012 of the key detection unit 400 so that the double key detection unit 500 can recognize that two keys are triggered at the same time. Thus, according the present invention, the key detection unit 400 plus the OR gate 502 forms the double key detection unit 500, which can determine that the two keys are triggered.

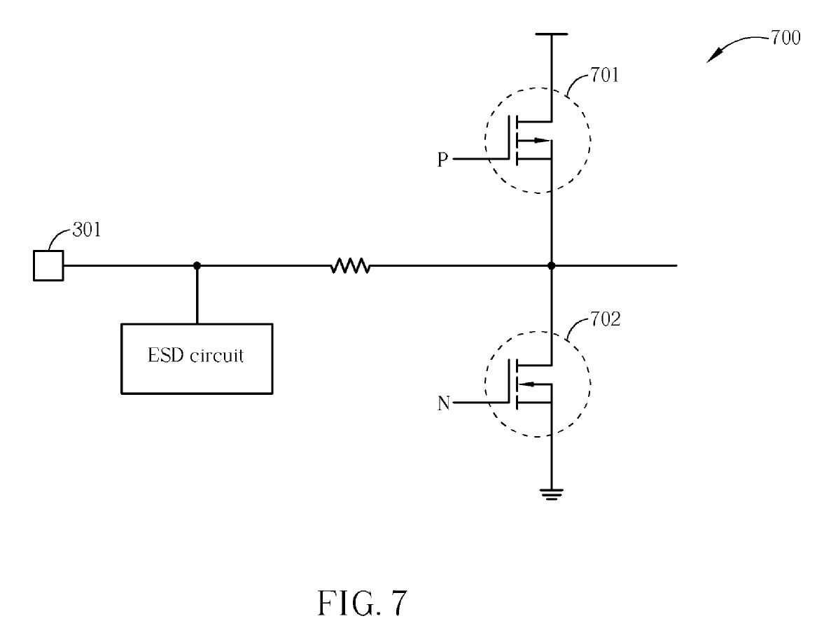

Please refer to FIG. 7. FIG. 7 is a diagram of a reference signal generation unit of the microcontroller 310 in FIG. 3. According to the embodiment of the present invention, since the data signals inputted to the microcontroller 310 are used as scanning signals of the plurality of keys 303, when the data signals are lost, the key detection unit 400 will fail due to no signals being inputted to the comparison signal end 4012. Thus, in this embodiment, the microcontroller 310 comprises a reference signal generation unit 700 for generating a reference signal, so as to prevent the key detection unit 400 from failure when the data signals are lost. The reference signal generation unit 700 comprises a pull-up switch 701 and a pull-down switch 702. The pull-up switch 701 and the pull-down switch 702 are controlled by a set of control signals P and N. In the meanwhile, only one of the pull-up switch 701 and the pull-down switch 702 is turned on, so that the signal of the data input port 301 is at a high level or a low level. When the data signals are inputted normally, the operation of the pull-up switch 701 and the pull-down switch 702 have no influence on the data input port 301, because the signal outside the microcontroller 310 is more intense than inside. However, when the data signals are lost, the data input port 301 is floating, so the operation of the pull-up switch 701 and pull-down switch 702 will generate corresponding signals to the first ends of the plurality of keys 303. Thus, the key detection unit 400 can detect the triggered key 303.

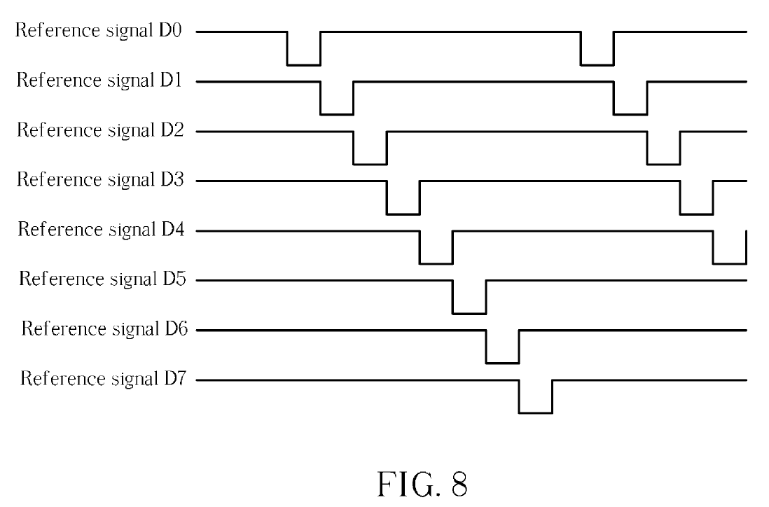

Please refer to FIG. 8. FIG. 8 is a waveform diagram of the reference signal generated by the reference signal generation unit 700 in FIG. 6. When each data input port 301 has a different reference signal, the key detection unit 400 can determine if the plurality of keys 303 are triggered. In this embodiment, each reference signal has a clock shift. At the same time, only one reference signal is at the low level. The reference signal D0 to the reference signal D7 are inputted to the data input ports 301 through the data line D0 to the data line D7 respectively. In the embodiment of the double key detection unit 500, to detect that the keys coupled to the data line D0 and D1 are triggered at the same time, the reference signal D0 and the reference signal D1 are inputted to the OR gate 502 and then inputted to the comparison signal end 4012.

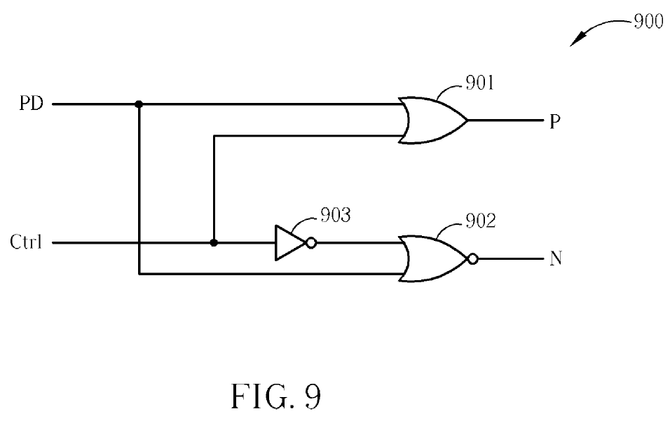

Please refer to FIG. 9. FIG. 9 is a diagram of the reference signal control unit 900 of the microcontroller 310. The reference signal control unit 900 provides the control signals Ctrl P and Ctrl N to the reference signal generation unit 700 in FIG. 6. The reference signal control unit 900 comprises an OR gate 901, a NOR gate 902, and an inverter 903. A first end of the NOR gate 902 is coupled to a second end the OR gate 901 through the inverter 903. A second end of the NOR gate 902 is coupled to a first end of the OR gate 901. The reference signal control unit 900 is controlled according to control signals PD and Ctrl. The control signal PD is used to turn on or turn off the reference signal generation unit 700. The control signal Ctrl is used to control the reference signal generation unit 700 to output a high level or a low level. When the data signals are inputted to the microcontroller 310 normally, the reference signal generation unit 700 will increase the power consumption of the microcontroller 310. Thus, when the microcontroller 310 receives the data signals normally, the control signal PD is set to 1 so as to turn off the reference signal generation unit 700. When the microcontroller 310 detects that the data signals are lost, the control signal PD is set to 0 so as to turn on the reference signal generation unit 700. Thus, the power consumption of the microcontroller 310 can be conserved. The following table shows the values of the control signals PD and Ctrl.

| PD | Ctrl | P | N | State |
|---|---|---|---|---|
| 0 | 0 | 0 | 0 | High level |
| 0 | 1 | 1 | 1 | Low level |
| 1 | X | 1 | 0 | Off |

In conclusion, the key system according to the present invention comprises a microcontroller and a plurality of keys. The first ends of the keys are coupled to a plurality of data input ports of the microcontroller respectively. The second ends of the keys are coupled to a key input port of the microcontroller. The key system utilizes the data signals inputted to the microcontroller as scan signals for the keys. The signal received by the key input port is detected to determine which key is triggered. Thus, one key input port is sufficient to detect which of the plurality of keys is triggered.

Those skilled in the art will readily observe that numerous modifications and alterations of the device and method may be made while retaining the teachings of the invention.

What is claimed is:

1. A key system capable of detecting if a plurality of keys are triggered comprising:
a microcontroller comprising a first data input end, a second data input end, and a key input port;
a first key, a first end of the first key coupled to the first data input end, and a second end of the first key coupled to the key input port; and
a second key, a first end of the second key coupled to the second data input end, and a second end of the second key coupled to the key input port.

2. The key system of claim 1, wherein the microcontroller comprises:
a first key detection unit for comparing a signal received by the key input port and a signal of the first data input end; and
a second key detection unit for comparing the signal received by the key input port and a signal of the second data input end.

3. The key system of claim 2, wherein the first key detection unit and the second key detection unit respectively comprise:
an XOR gate having two input ends for inputting the signal received by the key input port and the signal of the first data input end respectively;
a check unit coupled to an output of the XOR gate, comprising a plurality of flip-flops coupled in series and a NOR gate; and
a re-sampling unit coupled to an output end of the check unit.

4. The key system of claim 1, wherein the microcontroller comprises:
a double key detection unit for comparing the signal received by the key input port and a mixed signal of the first data input end and second data input end.

5. The key system of claim 4, wherein the double key detection unit comprises:
an OR gate having two input ends for inputting the signal of the first data input end and the signal of the second data input end respectively:
an XOR gate having a first input coupled to an output end of the OR gate, and a second input end for inputting the signal received by the key input port;
a check unit coupled to an output end of the XOR gate, comprising a plurality of flip-flops coupled in series and a NOR gate; and
a re-sampling unit coupled to an output end of the check unit.

6. The key system of claim 1, wherein the microcontroller comprises:
a reference signal generation unit for generating a reference signal for input to the first data input end or to the second data input end.

7. The key system of claim 6, wherein the reference signal generation unit comprises:
a pull-up switch having an output end coupled to the first data input end or the second data input end; and
a pull-down switch having an output end coupled to the first data input end or the second data input end.

8. The key system of claim 6, wherein the microcontroller comprises:
a reference signal control unit for turning on or turning off the reference signal generation unit.

9. The key system of claim 8, wherein the reference signal control unit comprises:
an OR gate having a first input end and a second input end; and
a NOR gate having a first input end coupled to the second input end of the OR gate through an inverter, and a second input end coupled to the first input end of the OR gate.

10. The key system of claim 1, further comprising:
a first diode coupled between the first end of the first key and the first data input end;
a second diode coupled between the first end of the second key and the second data input end; and
a pull-down resistor coupled between the key input port and a ground.

11. A method of detecting if a plurality of keys are triggered comprising:
providing a first key, a first end of the first key coupled to a first data input end of a microcontroller, and a second end of the first key coupled to a key input port of the microcontroller;
providing a second key, a first end of the second key coupled to a second data input end of the microcontroller, and a second end of the second key coupled to the key input port of the microcontroller; and
detecting a signal received by the key input port of the microcontroller to determine if the first key or the second key is triggered, or if the first key and the second key are triggered at the same time.

12. The method of claim 11, wherein detecting a signal received by the key input port of the microcontroller to determine if the first key or the second key is triggered, or the first key and the second key are triggered at the same time comprises:
if the signal received by the key input port of the microcontroller is a signal of the first data input end, determining that the first key is triggered.

13. The method of claim 11, wherein detecting a signal received by the key input port of the microcontroller to determine if the first key or the second key is triggered, or the first key and the second key are triggered at the same time comprises:
if the signal received by the key input port of the microcontroller is a signal of the second data input end, determining that the second key is triggered.

14. The method of claim 11, wherein detecting a signal received by the key input port of the microcontroller to determine if the first key or the second key is triggered, or the first key and the second key are triggered at the same time comprises:
if the signal received by the key input port of the microcontroller is a mixed signal of the first data input end and the second data input end, determining that the first key and the second key are triggered at the same time.
